(19) United States
(12) Patent Application Publication
(10) Pub. No.: US 2024/0263312 A1
(43) Pub. Date: Aug. 8, 2024

(54) PARYLENE COATING SYSTEM

(71) Applicant: VSI Parylene, Broomfield, CO (US)

(72) Inventors: Steven Scott Neely, Louisville, CO (US); Michael Todd Swanson, II, Denver, CO (US); Bradford Alan Gillette, Broomfield, CO (US); Brian J. Behne, Erie, CO (US)

(21) Appl. No.: 18/107,365

(22) Filed: Feb. 8, 2023

(51) Int. Cl. C23C 16/52; B23K 31/02

(52) U.S. Cl. CPC C23C 16/52; B23K 31/02; B23K 2101/12

(57) ABSTRACT

A parylene coating system comprising a single welded reaction and chamber assembly is disclosed, the welded reaction and chamber assembly comprising a reaction zone having a vaporizer and a pyrolysis zone, the vaporizer including a body with one or more openings and a loading door; a deposition chamber for holding one or more specimens and having an inlet, an outlet, a lid, and at least one view port; wherein the pyrolysis zone is positioned between the vaporizer and the deposition chamber and welded at a first end to the vaporizer using a first weldment and at a second, opposing end to the inlet of the chamber using a second weldment. The parylene coating system further comprises a pumping system coupled to the outlet of the chamber and configured to reduce an internal pressure of the assembly to within a target pressure range for parylene deposition.

### FIELD OF THE DISCLOSURE

The present disclosure relates generally to a coating system. In particular, but not by way of limitation, the present disclosure relates to systems, methods and apparatuses for a parylene coating system manufactured as a single welded assembly.

### DESCRIPTION OF RELATED ART

Parylene may be applied as a thin film coating to waterproof electronics, add dry lubricity, add a dielectric layer or enhance adhesion to other coatings. Parylene coatings are a popular choice in applications where reliability and performance are important, such as for industrial and consumer electronics, aerospace and medical applications, etc. Parylene deposition usually occurs in a low-pressure chamber, during which parylene deposits molecule by molecule onto parts or substrates placed in the deposition chamber. Currently, parylene coating systems are either large complex systems that are expensive, or smaller Research & Design (R&D) systems. In some circumstances, these smaller R&D systems suffer some deficiencies, notably a difficulty in holding up to production environments. Smaller R&D parylene coating systems use designs that cause the coating thickness range to be high (e.g., above a threshold). In some cases, parylene coating systems are prone to leaks. Additionally, or alternatively, leaks are difficult to detect in some prior art parylene coating systems. Currently used parylene coating systems often require difficult and/or frequent maintenance and are expensive, making them cost inefficient, especially for smaller R&D type projects.

Thus, there is a need for a refined parylene coating system that is not only more accessible from a size and cost standpoint, but is also scalable, robust, and provides minimal coating thickness tolerances. Additionally, a refined parylene coating system that is also easy to maintain and/or operate can help make it more accessible for use with a wide variety of parts and substrates and/or to a wider range of users.

The description provided in the description of related art section should not be assumed to be prior art merely because it is mentioned in or associated with this section. The description of related art section may include information that describes one or more aspects of the subject technology.

### SUMMARY OF THE DISCLOSURE

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

Currently most parylene coating systems use a multi-part assembly construction. For instance, parylene coating systems typically have a vaporizer, a pyrolysis tube, and a vacuum chamber (or deposition chamber), each of which is provided as a separate component. Since parylene deposition requires low-pressure conditions (e.g., ˜2-50 mTorr), each component of a parylene coating system is connected with vacuum fittings to help ensure that the low-pressure conditions in the vacuum chamber are maintained. Achieving and maintaining such low-pressure conditions requires each component of the coating system to have a precision connection interface, e.g., designed to hold vacuum. Additionally, the coating system requires numerous additional parts (e.g., connection hardware) to create the seal(s) around each component. For example, prior art coating systems require one or more O-rings and clamps (e.g., clamping rings) to seal the various different interfaces (e.g., interface between vaporizer and vaporizer door, interface between vaporizer and pyrolysis tube/zone, interface between pyrolysis tube and deposition chamber, interface between chamber body and viewport(s), chamber lid, cold trap, to name a few) of the coating system. In some circumstances, each connection point or interface introduces an opportunity for the coating system to leak, requiring reassembly or expensive/time consuming maintenance. Prior art coating systems also utilize a horizontal loaded vaporizer. Besides being ergonomically difficult (e.g., cumbersome to load), it is challenging to uniformly load the dimer powder into such vaporizers. In some instances, the non-uniform distribution of the dimer powder may lead to process variations, which further increases the cost associated with parylene coating. In some cases, deposition chambers also provide one or more off the shelf circular viewports to allow a user to visually check if the parts/substrates being coated are secured inside the chamber. In some cases, a gap is formed between the circular viewport(s), the O-ring (or another seal), and/or the body/wall of the deposition chamber, which is susceptible to filling up with parylene. Thus, there is a need for a refined parylene coating system that addresses one or more deficiencies of prior art coating systems.

Generally, aspects of the present disclosure are directed to a parylene coating system that is manufactured as a single welded assembly (herein referred to as a welded reaction zone and deposition chamber assembly). Specifically, but without limitation, the disclosed parylene coating system utilizes a single welded assembly for the vaporizer, pyrolysis tube/zone, and deposition chamber. Such a design helps enhance reliability, manufacturability, ease of assembly, and/or overall cost of the system compared to the prior art. By employing a single welded reaction zone and deposition chamber assembly, the parylene coating system enhances reliability by minimizing or reducing the likelihood of vacuum leaks occurring during use. Additionally, or alternatively, the parylene coating system enhances reliability (e.g., when considering maintenance cycles), as compared to the prior art, because it helps simplify the maintenance process by precluding disassembly and reassembly of the coating system. In some aspects, a single welded system also helps optimize manufacturability by allowing a smaller number of components/subassemblies to be manufactured and sourced, as compared to the prior art. For example, the reaction zone and deposition chamber assembly of the parylene coating system may be manufactured as a monolithic or unitary structure where the vaporizer is welded to a first end of the pyrolysis tube/zone and the deposition chamber is welded to a second, opposing end of the pyrolysis zone. In some embodiments, the vaporizer is a top loading vaporizer comprising a hinged vertical loading door (e.g., shown as loading door 125), which may provide for improved visibility and/or easier loading, as compared to prior art parylene coating systems. Additionally, a top loading vaporizer may be more ergonomic than a horizontal loaded vaporizer, making it easier to clean and/or inspect the interior of the vaporizer when loading the parylene dimer.

In some aspects, the techniques described herein relate to a system for thin-film deposition, including: a welded reaction zone and deposition chamber assembly, the welded reaction zone and deposition chamber assembly including: a reaction zone having a vaporizer and a pyrolysis zone, wherein the vaporizer includes a body having one or more openings and a loading door; a deposition chamber configured to hold one or more specimens, the deposition chamber including an inlet, an outlet, a lid, and at least one view port; wherein the pyrolysis zone is positioned between the vaporizer and the deposition chamber, and wherein the pyrolysis zone is welded at a first end to the vaporizer using a first weldment and at a second, opposing end to the inlet of the deposition chamber using a second weldment; and a pumping system, wherein the pumping system is coupled to the outlet of the deposition chamber.

In some aspects, the techniques described herein relate to a system, wherein the vaporizer, the deposition chamber, and the pyrolysis zone are formed as a monolithic or unitary construction, and wherein an internal pressure of the welded reaction zone and deposition chamber assembly is configured to be maintained within a target pressure range for thin-film deposition, wherein the target pressure range is between 1 mTorr to 50 mTorr.

In some aspects, the techniques described herein relate to a system, wherein: the loading door includes a vertical loading door; the vertical loading door is secured to the body using a hinge; the vertical loading door is shaped and sized to cover a first opening of the one or more openings, the first opening formed at a top end of the body of the vaporizer; and the vaporizer is configured to receive a powdered solid including a raw dimer material, wherein the raw dimer material is placed into the body of the vaporizer via the vertical loading door, and wherein the raw dimer material is configured to be deposited as a thin-film on the one or more specimens in the deposition chamber.

In some aspects, the techniques described herein relate to a system, wherein the body of the vaporizer includes a second opening positioned along a side of the body, and wherein the second opening is shaped and sized to receive the first end of the pyrolysis zone.

In some aspects, the techniques described herein relate to a system, wherein the at least one view port includes a plurality of viewports, including at least a first view port positioned on a first side of the deposition chamber and a second view port positioned on a second, different side of the deposition chamber.

In some aspects, the techniques described herein relate to a system, wherein the first view port includes an elliptical or oval shape, and the second view port includes a circular shape.

In some aspects, the techniques described herein relate to a system, wherein each of the first view port and the second view port include an elliptical shape, and one or more of: an aspect ratio of the first view port is different from an aspect ratio of the second view port; and a surface area of the first view port is different than a surface area of the second view port.

In some aspects, the techniques described herein relate to a system, wherein the first view port and the second view port include a different surface area, a different shape, a different depth, or a combination thereof.

In some aspects, the techniques described herein relate to a system, wherein the at least one view port includes a plurality of view ports, including at least a first view port and a second view port, and wherein each of the first view port and the second view port are shaped and sized to be received within a corresponding opening formed on a side of the deposition chamber, and wherein each of the first view port and the second view port are secured in the corresponding opening using O-ring gaskets.

In some aspects, the techniques described herein relate to a system, wherein the vaporizer is configured to receive a powdered solid to be deposited as a thin-film on the one or more specimens in the deposition chamber, and wherein the vaporizer is further configured to vaporize or sublimate the powdered solid into a first vapor.

In some aspects, the techniques described herein relate to a system, wherein the first vapor includes a dimer vapor, and wherein the pyrolysis zone is heated to heat the dimer vapor and transform the dimer vapor to a monomer vapor, and wherein the monomer vapor flows into the deposition chamber.

In some aspects, the techniques described herein relate to a system, wherein: each of the one or more specimens is selected from a group consisting of an electrical part or wafer, a polymer tube, and a medical device guide wire; the thin-film deposition includes a parylene deposition; and the pyrolysis zone does not include a glass quartz lining.

In some aspects, the techniques described herein relate to a method of manufacturing a welded reaction zone assembly configured for use in a thin-film deposition process, the method including: providing a vaporizer having a body and a vertical loading door, wherein the vertical loading door is shaped and sized to fit over a first opening formed at a top end of the body; providing a deposition chamber having an inlet, an outlet, and a lid, and wherein the deposition chamber is configured to hold one or more specimens; providing a pyrolysis zone having a first end and a second end; welding the first end of the pyrolysis zone to a second opening formed on a side of the body of the vaporizer and welding the second end of the pyrolysis zone to an inlet of the deposition chamber such that, the pyrolysis zone is positioned between the vaporizer and the deposition chamber, and the vaporizer, the deposition chamber, and the pyrolysis zone are formed as a unitary or monolithic construction; forming one or more viewport openings on one or more sides of the deposition chamber; and affixing a viewport in each of the one or more viewport openings on the one or more sides of the deposition chamber.

In some aspects, the techniques described herein relate to a method, wherein forming the one or more viewport openings on the side of the deposition chamber includes: forming a first viewport opening having a first aspect ratio, wherein the first viewport opening is shaped and sized to receive a first viewport having a same or approximately the same aspect ratio as the first aspect ratio; and forming a second viewport opening having a second, different aspect ratio, wherein the second viewport opening is shaped and sized to receive a second viewport having a same or approximately the same aspect ratio as the second aspect ratio.

In some aspects, the techniques described herein relate to a method, wherein each of the one or more viewports includes a window, and wherein each of the one or more viewport openings includes a receiving port and a flange, each of the receiving port and the flange including an exterior side and an interior side, and wherein affixing each of the one or more viewports in a corresponding viewport opening includes: positioning the window on the exterior side of the receiving port; positioning the flange such that at least a portion of a perimeter of the window is arranged within a groove formed between the exterior side of the receiving port and the interior side of the flange; sealing the window in the groove using a plurality of O-ring gaskets, including at least a first O-ring gasket positioned between the exterior side of the receiving port and a first side of the window and a second O-ring gasket positioned between the interior side of the flange and a second, opposing side of the window; wherein the first side of the window faces an interior of the deposition chamber and the second side of the window faces an exterior of the deposition chamber.

In some aspects, the techniques described herein relate to a method, wherein: each of the one or more specimens is selected from a group consisting of an electrical part or wafer, a polymer tube, and a medical device guide wire; the thin-film deposition includes a parylene deposition; and the pyrolysis zone does not include a glass quartz lining.

In some aspects, the techniques described herein relate to a method of using a welded reaction zone and deposition chamber assembly, the welded reaction zone and deposition chamber assembly configured for use in a thin-film deposition process, the method including: providing the welded reaction zone and deposition chamber assembly, wherein the welded reaction zone and deposition chamber assembly includes: a vaporizer having a body and a vertical loading door, wherein the vertical loading door is shaped and sized to fit over a first opening formed at a top end of the body; a deposition chamber configured to hold one or more specimens, the deposition chamber including an inlet, an outlet, a lid, and at least one view port; and a pyrolysis zone positioned between the vaporizer and the deposition chamber, wherein the pyrolysis zone is welded at one end to the vaporizer using a first weldment and at another, opposing end to the inlet of the deposition chamber using a second weldment; coupling a pumping system to the outlet of the deposition chamber; affixing the one or more specimens to an interior of the deposition chamber; loading a powdered solid through the vertical loading door of the vaporizer, wherein the powdered solid is to be deposited as a thin-film on the one or more specimens in the deposition chamber; vaporizing or sublimating the powdered solid into a first vapor such that the first vapor flows into the pyrolysis zone; heating, using the pyrolysis zone, the first vapor such that the first vapor transforms into a second vapor and flows into the deposition chamber; and pumping down, using the pumping system, the deposition chamber until an internal pressure of the welded reaction zone and deposition chamber assembly is within a target pressure range for thin-film deposition.

In some aspects, the techniques described herein relate to a method, wherein the vaporizer, the deposition chamber, and the pyrolysis zone are formed as a monolithic or unitary construction based at least in part on the first and the second weldments, and wherein the target pressure range is between 1 mTorr to 50 mTorr.

In some aspects, the techniques described herein relate to a method, wherein an internal pressure of the welded reaction zone and deposition chamber assembly is configured to be maintained within the target pressure range for thin-film deposition.

In some aspects, the techniques described herein relate to a method, wherein: each of the one or more specimens is selected from a group consisting of an electrical part or wafer, a polymer tube, and a medical device guide wire; the thin-film deposition includes a parylene deposition; and the pyrolysis zone does not include a glass quartz lining.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1 is an example of a parylene coating system utilizing a welded reaction zone and deposition chamber assembly, according to various aspects of the disclosure.

FIG. 2 is another example of a parylene coating system utilizing a welded reaction zone and deposition chamber assembly, according to various aspects of the disclosure.

FIG. 3 illustrates a detailed view of a viewport affixed in a viewport opening of a deposition chamber using one or more gaskets, such as O-ring gaskets, according to various aspects of the disclosure.

FIG. 4A illustrates an example of a method of manufacturing a welded reaction zone and deposition chamber assembly configured for use in a thin-film deposition process, according to various aspects of the disclosure.

FIG. 4B illustrates an example of a method of using a welded reaction zone and deposition chamber assembly configured for use in a thin-film deposition process, according to various aspects of the disclosure.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Generally, aspects of the present disclosure are directed to a parylene coating system comprising a welded reaction zone and deposition chamber assembly (also referred to as a single welded assembly). Specifically, but without limitation, the disclosed parylene coating system utilizes a single welded assembly for the vaporizer, pyrolysis zone tube (or simply, pyro tube), and deposition chamber (or chamber). The welded reaction zone and deposition chamber assembly comprises a reaction zone having a vaporizer and pyrolysis zone (or pyrolysis tube), and a deposition chamber. The vaporizer of the reaction zone may include a vaporizer body and a hinged top loading door (or vertical loading door), where the vaporizer body includes an outlet that is coupled to the pyrolysis zone. The pyrolysis zone is positioned between the vaporizer and the deposition chamber, where the pyrolysis zone is welded at one end to the vaporizer body using a first weldment and at another, opposing end to an inlet of the deposition chamber using a second weldment. In some cases, an outlet of the deposition chamber is coupled to a vacuum pumping system, where the vacuum pumping system is configured to pump down the welded reaction zone and deposition chamber assembly until an internal pressure of the assembly is within a target pressure range (e.g., between 1 mTorr to 50 mTorr) for thin-film deposition.

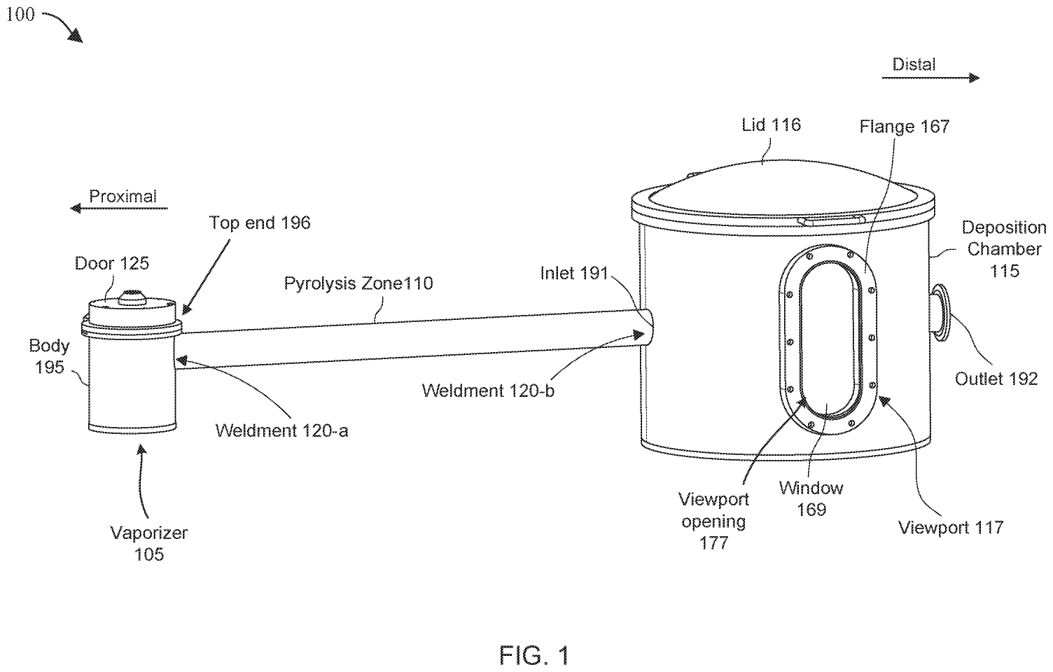

Parylene films are usually grown molecule-by-molecule as the vapor deposits on specimens (e.g., parts, substrates, wafers, etc.) in a low-pressure or vacuum chamber, also referred to as a deposition chamber (e.g., shown as deposition chamber 115 in FIG. 1). In some examples, the low-pressure or vacuum chamber may be operated at or near ambient/room-temperature, for instance, anywhere between 17-25 degrees Celsius. In some cases, the internal pressure in the deposition chamber 115 may need to be brought down below 50 mTorr for parylene deposition to occur.

Currently, most parylene coating systems utilize a multi-part assembly construction. For instance, parylene coating systems typically have a vaporizer, a pyrolysis tube, and a vacuum chamber (or deposition chamber), each of which is provided as a separate component. The pyrolysis tube is positioned between the vaporizer and deposition chamber and receives a dimer vapor (e.g., vaporized in the vaporizer) and heats said dimer vapor until it transforms into a monomer vapor. This monomer vapor then flows into the deposition chamber comprising the electrical parts, substrates, wafers, etc., to be coated. Since parylene deposition requires low-pressure conditions, each component of a parylene coating system is connected with vacuum fittings to maintain said low pressure conditions. Achieving and maintaining such low-pressure conditions requires each component of the coating system to have a precision connection interface, e.g., designed to hold vacuum. Additionally, the coating system requires numerous additional parts (e.g., connection hardware) to create the seal(s) around each component. For example, prior art coating systems require one or more O-rings, clamps, and/or clamping rings to seal the various different connection point or interfaces (e.g., interface between vaporizer and vaporizer door, interface between vaporizer and pyrolysis tube, interface between pyrolysis tube and deposition chamber, interface between chamber body and viewport(s), chamber lid, etc.) of the coating system. In some circumstances, each connection point/interface introduces an opportunity for the coating system to leak, requiring reassembly or expensive/time consuming maintenance.

Turning now to FIG. 1, which illustrates an example of a welded reaction zone and deposition chamber assembly 100 (also referred to as welded assembly 100), according to various aspects of the disclosure. As seen, the welded assembly 100 comprises a vaporizer 105 having a loading door 125, a deposition chamber 115, and a pyrolysis tube 110 (or pyrolysis zone 110) positioned between the vaporizer 105 and the deposition chamber 115. In some cases, the vaporizer 105 and the pyrolysis zone 110 may collectively be referred to as a “reaction zone”. In some embodiments, the chamber 115 has an inlet 191, an outlet 192, a lid 116, and at least one view port 117 having a window 169. As seen, the vaporizer 105 is welded to one end (e.g., proximal end) of the pyrolysis zone 110 using a first weldment 120-a. Additionally, the second, opposing end (e.g., distal end) of the pyrolysis zone 110 is welded to the inlet 191 of the deposition chamber 115 using a second weldment 120-b. In this way, the vaporizer 105, the pyrolysis zone 110, and the deposition chamber 115 are formed as a monolithic or unitary construction, which serves to reduce the number of seals, O-rings, clamps or clamping rings, etc., required to vacuum seal the various subassemblies of the parylene coating system.

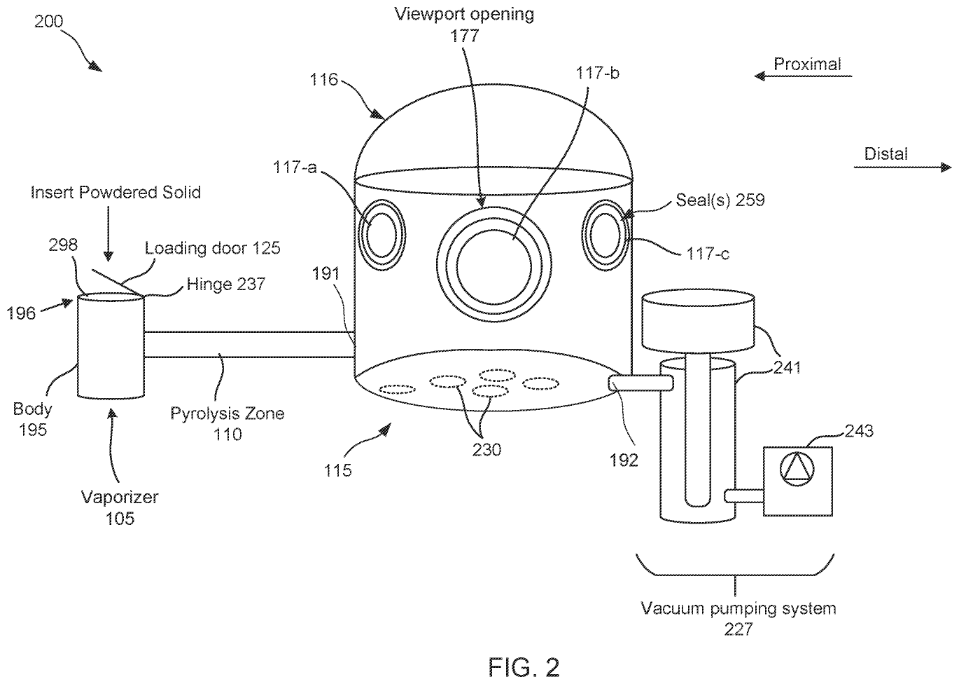

In some examples, the loading door 125 of the vaporizer is a hinged top loading (or vertical loading) door that is movable in a vertical direction (up-down direction in the page). For example, as seen in FIG. 2, the loading door 125 is coupled to a top end of the vaporizer body 195 using a hinge 237. In some aspects, the use of a vertically oriented vaporizer facilitates easier loading, cleaning, maintenance, and/or enhanced visibility, as compared to the horizontally loaded vaporizers seen in prior art coating systems. In some cases, a vertically loaded vaporizer, such as vaporizer 105, may also allow for a more uniform distribution of the parylene dimer (e.g., loaded as a powdered solid), which helps minimize or reduce process variations.

As noted above, the deposition chamber 115 comprises a lid 116 and at least one viewport 117 having a window 169. The at least one viewport 117 is shaped and sized to securely fit in a respective viewport opening formed on the side of the deposition chamber 115. In some embodiments, the aspect ratio (e.g., width to height, which maybe 1:4 or 1:2) of the viewport 117 is selected to optimize the viewing area (i.e., allow for a larger viewport), while at the same time ensuring integrity of the vacuum or low-pressure conditions in the chamber 115. In some cases, the sealing system used to seal the viewport 117 and the chamber 115 may be optimized, where the optimization comprises determining an adequate groove depth and/or O-ring thickness to avoid metal to glass contact while maintaining a tight seal and an adequate space for minimal parylene buildup in the gap. In this example, the viewport 117 has an oval or elliptical shape, but other shapes of viewports are contemplated in different embodiments. Additionally, in some embodiments, more than one viewport 117 may be provided on the sides of the deposition chamber 115. As seen in FIG. 2, the parylene coating system 200 comprises a single welded assembly having a deposition chamber 115, where the deposition chamber includes three viewports (e.g., viewports 117-a, 117-b, 117-c) positioned on the sides of the deposition chamber 115. Additionally, one viewport (e.g., viewport 117-b) of the chamber has a larger surface area than the other two viewports 117 (i.e., viewports 117-a, 117-c). Other shapes, configurations, aspect ratios, etc., of viewports 117 are contemplated and the examples listed herein are not intended to be limiting. In some other cases, the deposition chamber 115 in FIG. 1 may include an additional viewport on an opposing side (e.g., back side—not visible from this angle) of the deposition chamber. In some cases, this second viewport may have a different shape (e.g., circular, instead of elliptical), a different surface area, and/or a different aspect ratio as compared to the viewport 117 on the front side of the deposition chamber 115. In some examples, the second viewport may allow auxiliary equipment, such as, but not limited to, a tumbling system, a calibration system, and/or a measurement system to be added on (or coupled to) the deposition chamber 115.

In some cases, the pyrolysis tube/zone 110 does not include a glass quartz lining, as typically utilized in prior art pyro tubes, which helps simplify construction of the pyrolysis tube/zone 110. In some examples, the pyrolysis tube/zone 110 may be composed of metals or metal alloys that are designed to withstand the temperature and chemical environment inside the pyrolysis tube 110 during use. Prior art pyro tubes utilize a glass quartz lining (or alternatively, an inner quartz tube) for protecting the outer metal tube from heated gasses, prevent degradation of metal in the pyro tube (i.e., since the monomer gas reacts with common metals causing corrosion), etc. However, glass quartz liners need to be cleaned or replaced relatively frequently, which drives up maintenance time and/or cost. Additionally, the delicate nature of glass quartz liners (prone to breaking) is another concern to end-users. As such, pyro tubes utilizing glass quartz liners (or another type of inner tube or liner for protecting the outer metal tube from corrosion) often times do not provide adequate protection against corrosion over the long term. In some cases, pyro tubes utilizing glass quartz liners may need to be replaced when such corrosion occurs. Aspects of the present disclosure are directed to utilizing a pyrolysis tube/zone 110 that is composed of specially designed metal alloys that provide greater resistance to corrosion, simpler assembly, lower maintenance time and/or cost, to name a few non-limiting examples, as compared to the prior art.

In some examples, the pyrolysis tube/zone 110, the vaporizer, and the deposition chamber may be composed of the same or different material (e.g., metal or alloy, such as corrosion resistant alloy). Some non-limiting examples of corrosion resistant alloys and/or metals that may be used to form the pyrolysis tube/zone (or alternatively, the vaporizer and/or the deposition chamber) include corrosion-resistant steel (e.g., containing at least 10.5% chromium), ferritic stainless steels, Martensitic stainless steel, Austenitic stainless steel, duplex stainless steel (e.g., formed with a balance of Chromium, Nickel, and Molybdenum between that of Ferritic and Austenitic stainless steels), Super Duplex stainless steel (e.g., comprising alloying elements such as Copper and Tungsten in addition to Chromium, Nickel, and Molybdenum), Nickel base alloys, Titanium base alloys, Molybdenum base alloys, Zirconium base alloys, Tantalum base alloys, etc. Other types of alloys/metals may be used to form the different components and elements (e.g., pyro tube/zone, vaporizer, deposition chamber) of the parylene coating system and the examples listed above are not intended to be limiting.

FIG. 2 illustrates an example of a parylene coating system 200 utilizing a single welded reaction zone and deposition chamber assembly, according to various aspects of the disclosure. The parylene coating system 200 implements one or more aspects of the welded reaction zone and deposition chamber assembly 100 previously described in relation to FIG. 1, and comprises a vaporizer 105, a chamber 115, and a pyrolysis tube or zone 110. In some cases, the pyrolysis zone 110 and vaporizer 105 may collectively be referred to as a reaction zone. Additionally, the pyrolysis zone 110 may be welded at one end (e.g., proximal end) to the vaporizer 105 and at another end (e.g., distal end) to an inlet 191 of the deposition chamber 115. In some examples, the vaporizer 105 comprises a hinged loading door 125 (e.g., top or vertical loading door) coupled at or near a top end of the vaporizer 105 using a hinge assembly 237. The loading door 125 is shaped and sized to cover an opening formed on the top end of the vaporizer 105. In some cases, a powdered solid (e.g., parylene powder or dimer) can be loaded into the vaporizer 105 through the loading door 125. The loading door 125 is configured to provide a tight vacuum seal fit when closed/latched over the opening at the top of the vaporizer. This allows the low-pressure conditions (e.g., ˜1-50 mTorr) in the welded reaction zone and deposition chamber assembly to be maintained during use. In some embodiments, this tight vacuum seal fit between the loading door 125 and the top opening of the vaporizer may be achieved using an O-ring (or another applicable component), where the O-ring is arranged on the vaporizer body 195 and configured to seal to the lid (i.e., vertical loading door 125) of the vaporizer.

In some cases, the outlet 192 of the deposition chamber can be connected to a vacuum pumping system 227, the vacuum pumping system 227 comprising at least a cold trap 241 and one or more pump(s) 243. Some non-limiting examples of pumps 243 that can be utilized in the parylene coating system 200 include mechanical pumps (e.g., roughing pumps), Roots blower type pumps, and/or turbomolecular or turbo pumps.

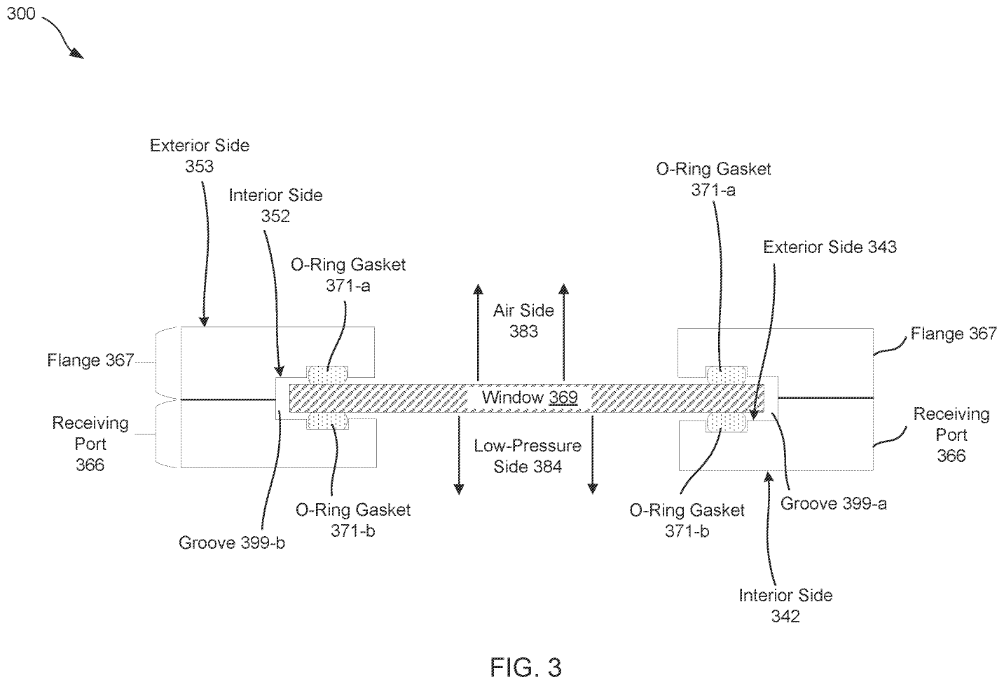

In some cases, the deposition chamber 115 includes one or more viewports 117 (e.g., viewports 117-a, 117-b, 117-c) affixed within openings along the sides of the chamber wall. A tight seal (e.g., seal 259, which may be achieved using one or more O-ring gaskets) can be provided to secure the viewports 117 in the viewport openings of the chamber wall, which allows low pressure conditions (e.g., between 1-50 mTorr) needed for parylene deposition to be maintained within the welded reaction zone and deposition chamber assembly. In some cases, the tight seal, such as seal 259, may be achieved using an O-ring gasket (or alternatively, through any other applicable means known or contemplated in the art), further described in relation to FIG. 3. In some embodiments, the lid 116 of the chamber 115 can also include an O-ring gasket. Further, the lid 116 and the body of the deposition chamber 115 may be coupled or joined using a hinge mechanism. Additionally, or alternatively, the lid 116 may include a lockable latching mechanism (e.g., over-center latching mechanism). While not necessary, the lid 116 may also include a viewport (e.g., a window or glass) in some embodiments.

In some embodiments, the deposition chamber 115 is configured to hold one or more specimens 230, where each of the one or more specimens is selected from a group consisting of an electrical part or wafer, a polymer tube, and a medical device guide wire. Other types of specimens besides the ones listed above are contemplated in different embodiments, and the examples listed herein are not intended to be limiting. Additionally, it should be noted that different types of specimens (e.g., some with electrical uses, such as wafers; and some without electrical uses, such as polymer tubes) can be affixed to the inside of the deposition chamber 115 at the same time and simultaneously coated with parylene (or another thin-film).

Thus, the present disclosure provides a thin-film deposition or coating system using a single welded assembly for the vaporizer (e.g., vaporizer 105), pyrolysis tube or zone (e.g., pyrolysis zone 110), and deposition chamber 115. Such a design may help enhance the reliability, manufacturability, ease of assembly, and overall cost of the coating system compared to the prior art. In some cases, the welded reaction zone assembly comprising the vaporizer, pyro tube, and chamber can be provided as a single plug and play assembly that can be directly coupled to a vacuum pumping system, which helps reduce set-up time.

As can be appreciated, the top loading vaporizer 105 is easier to inspect, easier to load, and/or easier to clean, as compared to prior art vaporizers. In some instances, the top loading vaporizer 105 also allows for easier viewing of the dimer and vaporizer zone. Additionally, the larger viewport and/or more optimal aspect ratio of the viewport helps enhance the visibility of the load (i.e., specimens or wafers affixed to the inside of the chamber) during use. In some aspects, the larger viewport 117 allows for easier viewing inside the chamber 115 because it allows more light to enter the chamber, i.e., in addition to the larger viewing area. In some instances, when the lid 116 of the vacuum chamber also includes a viewport or glass, visibility is further enhanced by providing users with different viewing angles to the interior of the chamber.

Turning now to FIG. 3, which illustrates a detailed view of a viewport assembly 300, according to various aspects of the disclosure. The viewport assembly 300 comprises a viewport or window 369 affixed in a viewport opening on a side of a deposition chamber (e.g., deposition chamber 115 in FIGS. 1 and/or 2). In some cases, the deposition chamber comprises one or more viewport openings along its sides, where each of the one or more viewport openings is shaped and sized to receive a respective viewport (e.g., a window or glass). As used herein, the term “viewport opening” may be used to collectively refer to the flange and receiving port described in further detail below. Alternatively, the term “viewport opening” may be used to refer to the receiving port (e.g., receiving port 366) or the grooves (e.g., grooves 399-a, 399-b) formed between the flange 367 and the receiving port 366.

As seen in FIG. 3, the viewport assembly 300 comprises a window 369 that is “sandwiched” between a receiving port 366 on the deposition chamber and a flange 367 (e.g., metal flange, such as flange 167 in FIG. 1). Here, one side (shown as exterior or air side 383) of the window 369 faces the exterior of the deposition chamber, while another side (shown as interior or low-pressure side 384) faces the interior of the deposition chamber. Additionally, at least a portion of the perimeter of the window is clamped between the flange 367 and the receiving port 366. Specifically, at least a portion of the window 369 is received within a groove 399, where the groove is formed between an exterior side 343 of the receiving port and an interior side 352 of the flange 367. The exterior side 353 of the flange 367 is positioned towards an exterior/air side 383 of the deposition chamber. In some embodiments, the interior side 342 of the receiving port 366 is arranged to be flush or substantially flush against the exterior wall of the deposition chamber.

In some cases, one or more O-ring gaskets 371 (or simply O-rings) are employed to provide an elastomeric seal between the window 369 and the deposition chamber. In this example, a first O-ring 371-a is positioned in a gap or groove 399-a between the window 369 and the flange 367, while a second O-ring 371-b is positioned in another gap or groove 399-b between the window 369 and the receiving port 366. The O-rings are formed of a compressible material, such as a fluoroelastomer, rubber, a polymer, Nitrile, Ethylene Propylene (EPDM Rubber), Silicone, Fluorocarbon, PTFE (Teflon), or any other applicable material. Some of the factors that may be considered before selecting a particular material for the O-ring(s) include, but are not limited to, operating conditions, chemical compatibility (e.g., compatibility with parylene dimer vapor in the interior of the deposition chamber), sealing pressure (e.g., <1 mTorr), temperature, durometer or hardness, and/or size. In some cases, the inner O-ring gasket 371-b and the outer O-ring gasket 371-b may be composed of the same or a different material.

As noted above, some aspects of the present disclosure are directed to optimizing the sealing system used to seal the viewport and the chamber, where the optimization comprises determining an adequate depth for the groove(s) 399 and thickness of O-ring(s) 371 that enables a tight seal to be formed between the window 369 and the viewport opening (i.e., comprising the flange 367 and the receiving port 366), while reducing or minimizing gaps that can get filled with parylene. In some examples, each of the O-ring gasket(s) 371 may be configured to extend toward a respective one of the air side 383 and the low-pressure side 384. In other words, the O-ring gaskets 371 may occupy a substantial portion of the volume of the grooves 399, which helps reduce the likelihood of parylene depositing in said grooves.

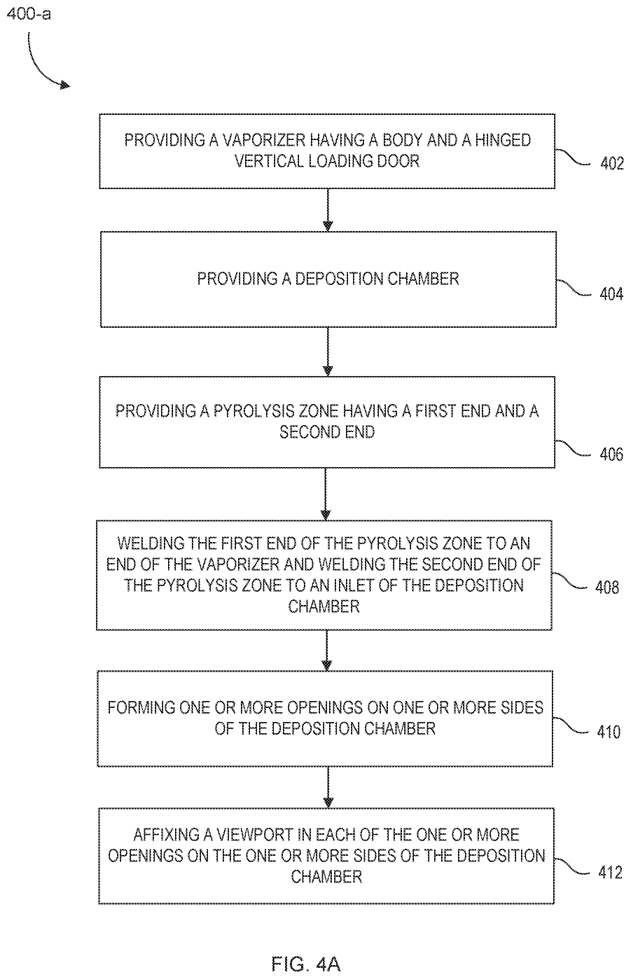

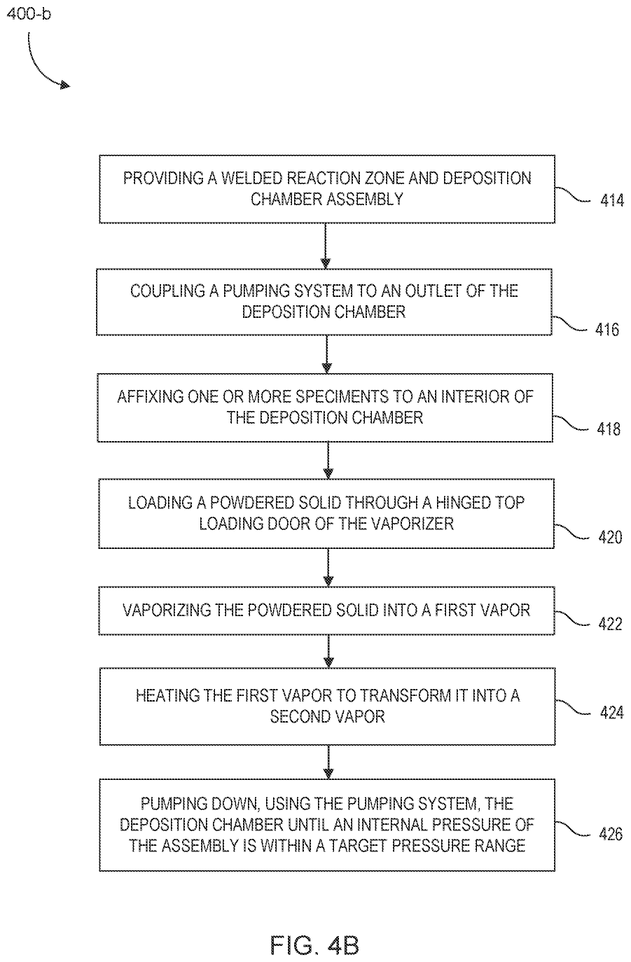

FIG. 4A illustrates an example of a method 400-a for manufacturing a welded reaction zone and deposition chamber assembly configured for use in a thin-film deposition process, according to various aspects of the disclosure.

A first operation 402 comprises providing a vaporizer having a body and a hinged vertical loading door. In some examples, the vertical loading door is positioned at or near an opening formed at a top end of the vaporizer. For example, the vaporizer 105 shown in FIGS. 1 and/or 2 comprises a body 195 and a loading door 125, where the loading door 125 is coupled at or near a top end 196 of the vaporizer body 195 using the hinge 237. In some embodiments, the loading door 125 is shaped and sized to cover the opening 298 formed at the top end 196 of the vaporizer 105.

A second operation 404 comprises providing a deposition chamber (e.g., deposition chamber 115 in FIGS. 1 and 2), where the deposition chamber comprises an inlet, an outlet, and a lid. In some embodiments, the deposition chamber is configured to hold one or more specimens. As shown and described in relation to FIGS. 1 and/or 2, the deposition chamber 115 comprises an inlet 191, an outlet 192, and a lid 116. Additionally, the deposition chamber 115 is configured to hold one or more specimens 230, where the specimens 230 are affixed to an interior of the deposition chamber.

A third operation 406 comprises providing a pyrolysis zone (e.g., pyrolysis zone 110) having a first end and a second end.

A fourth operation 408 comprises welding the first end of the pyrolysis zone to an end of the vaporizer (e.g., an opening formed on a side of the vaporizer body 195) and welding the second end of the pyrolysis zone to the inlet (e.g., inlet 191) of the deposition chamber. In some examples, the pyrolysis zone (e.g., pyrolysis zone 110) is positioned between the vaporizer 105 and the deposition chamber and a first weldment 120-a is used to weld/secure the pyrolysis zone 110 to the vaporizer body 195. Additionally, a second weldment 120-b is used to weld/secure the pyrolysis zone to the deposition chamber 115. As seen in FIGS. 1 and/or 2, the left end of the pyrolysis zone 110 is welded/secured over an opening formed on the side of the vaporizer 105 using the first weldment 120-a, while the right end of the pyrolysis zone 110 is welded/secured over the inlet 191 formed in the side of the deposition chamber 115 using the second weldment 120-b. In this way, the vaporizer, the deposition chamber, and the pyrolysis zone are formed as a unitary or monolithic construction. As a result, the vaporizer, the chamber, and the pyrolysis zone of the welded reaction zone assembly are configured to have the same or substantially the same internal pressure (e.g., at or around atmospheric pressure when the vacuum pumping system is not connected or is turned OFF; at or around a target pressure, such as 1-50 mTorr, when the vacuum pumping system is turned ON).

A fifth operation 410 comprises forming one or more viewport openings on one or more sides of the deposition chamber.

A sixth operation 412 comprises affixing a viewport in each of the one or more viewport openings on the one or more sides of the deposition chamber. As shown in FIGS. 1 and/or 2, the deposition chamber 115 comprises one or more viewports 117 on one or more sides of the deposition chamber, where each of the one or more viewports 117 is affixed in a viewport opening on the side of the deposition chamber. The deposition chamber 115 in FIG. 1 comprises a single viewport opening 177 and a viewport 117 affixed in said viewport opening. Furthermore, the deposition chamber 115 in FIG. 2 comprises three viewport openings 177 and three viewports 117 positioned on the side of the deposition chamber 115.

FIG. 4B illustrates an example of a method 400-b of using a welded reaction zone and deposition chamber assembly, according to various aspects of the disclosure. The welded reaction zone and deposition chamber assembly may be similar or substantially similar to the assemblies described herein, including at least in relation to FIGS. 1, 2, and/or 4A. In some embodiments, the welded reaction zone and deposition chamber assembly is configured for use in a thin-film deposition process (e.g., parylene deposition).

A first operation 414 comprises providing the welded reaction zone and deposition chamber assembly, wherein the welded reaction zone and deposition chamber assembly comprises a vaporizer 105 having a body 195 and a loading door (e.g., a vertical loading door 125), a deposition chamber 115 configured to hold one or more specimens 230, and a pyrolysis zone 110. In some cases, the vertical loading door is shaped and sized to fit over a first opening formed at a top end of the body 195.

In some embodiments, the vaporizer (e.g., vaporizer 105 in FIGS. 1 and/or 2) has a generally cylindrical shape having a radius anywhere between 1-5 inches and a height anywhere between 1-10 inches. Additionally, the vaporizer may have one or more openings including at least a first opening (e.g., opening 298) formed at a top end of the vaporizer body 195 for receiving the vertical loading door 125 and a second opening formed on a side of the vaporizer body 195 for receiving one end of the pyrolysis zone 110. The second opening formed on the side of the vaporizer 105 is shaped and sized to receive at least a portion of the pyrolysis zone 110 and has a radius that is anywhere between 0.25-2 inches.

In some embodiments, the deposition chamber has a generally cylindrical shape having a radius anywhere between 3-15 inches and a height anywhere between 2-28 inches. Additionally, or alternatively, the deposition chamber has an internal volume that is anywhere between 55 cubic inches and 20,000 cubic inches. The deposition chamber comprises an inlet (e.g., inlet 191), an outlet (e.g., outlet 192), a lid (e.g., lid 116), and at least one viewport (e.g., viewport 117). The lid 116 is configured to be arranged such that it covers an opening formed at the top end of the chamber body. In some embodiments, the lid 116 is secured to the top end of the chamber body using a hinge mechanism/assembly, or through any other applicable means known in the art. In some examples, the lid of the deposition chamber comprises a hemisphere (resembling a dome), as shown in FIGS. 1 and 2. Alternatively, the lid may be flat and flush or substantially flush against the top opening of the deposition chamber.

In some embodiments, the pyrolysis zone 110 is positioned between the vaporizer 105 and the deposition chamber 115 of the assembly. Specifically, the pyrolysis zone may be positioned such that it couples to (or interfaces with) one side of the vaporizer body and an inlet of the deposition chamber, as shown in FIGS. 1 and/or 2. In some embodiments, the inlet of the deposition chamber is shaped and sized to receive at least a portion of the pyrolysis zone and has a radius that is anywhere between 0.25-2 inches. While not necessary, the inlet of the deposition chamber may have the same or similar shape and/or dimensions as the second opening formed on the side of the vaporizer body 195.

Furthermore, in some cases, the pyrolysis zone 110 is welded at one end to the vaporizer 105 and at another, opposing end to the inlet 191 of the deposition chamber 115 using a first and a second weldment 120-a and 120-b, respectively. In some cases, one end of the pyrolysis zone 110 is welded onto, or over, an opening formed on the side of the vaporizer body 195. Additionally, the other end of the vaporizer is welded onto, or over, the inlet formed on the side of the deposition chamber. In one non-limiting example, the pyrolysis zone has a cylindrical cross-section having a cross-sectional area of around 7 square inches. The pyrolysis zone 110 extending between the vaporizer 105 and the deposition chamber 115 may have a length that is anywhere between 7 and 45 inches.

A second operation 416 comprises coupling a pumping system, such as vacuum pumping system 227 in FIG. 2, to the outlet 192 of the deposition chamber.

A third operation 418 comprises affixing one or more specimens (e.g., specimens 230) to an interior of the deposition chamber 115.

A fourth operation 420 comprises loading a powdered solid through the hinged top loading door 125 of the vaporizer 105, where the powdered solid is to be deposited as a thin-film on the one or more specimens 230 in the deposition chamber 115.

A fifth operation 422 comprises vaporizing the powdered solid into a first vapor, based at least in part on heating the powdered solid in the vaporizer 105. The first vapor flows into the pyrolysis zone 110. A sixth operation 424 comprises heating the first vapor to transform it into second vapor. In some cases, the first vapor is heated using the pyrolysis zone 110. Once the second vapor is produced, it flows into the deposition chamber 115.

A seventh operation 426 comprises pumping down, using the pumping system, the deposition chamber 115 until an internal pressure of the welded reaction zone and deposition chamber assembly is within a target pressure range for thin-film deposition (e.g., parylene deposition).

It should be noted that the example dimensions described above are not intended to be limiting and different shapes, sizes, cross-sectional areas, etc., are contemplated in different embodiments without departing from the scope and spirit of the present disclosure. For instance, in some cases, the pyrolysis zone 110 may have a length greater than 45 inches. In one non-limiting example, the pyrolysis zone 110 may have a length of around 5 feet (or 60 inches). In another non-limiting example, the pyrolysis zone 110 may have a cross-sectional area of around 10 square inches. Additionally, or alternatively, the pyrolysis zone 110 may have a rectangular or square cross-sectional shape (i.e., in lieu of a cylindrical cross-sectional shape). Similarly, in some embodiments, the deposition chamber may have a radius that is greater than 15 inches, for instance, at least 20 inches. Additionally, or alternatively, the deposition chamber may have a height of at least 30 inches, in some embodiments. In some cases, the internal volume of the deposition chamber may be greater than 20,000 cubic inches, for instance, at least 25,000 cubic inches. Furthermore, the internal volume of the deposition chamber may or may not include the volume of the dome-shaped or hemispherical lid.

In some examples, the vaporizer, the deposition chamber, and the pyrolysis zone described above may be formed as a monolithic or unitary construction based at least in part on the first and the second weldments 120-a and 120-b, respectively. Additionally, the target pressure range for thin-film deposition (e.g., parylene deposition) may be anywhere between 1 mTorr to 50 mTorr, although other target pressure ranges are also contemplated in different embodiments. In some instances, the vaporizer, the pyrolysis zone, and the deposition chamber may have the same or similar internal pressure since the welded reaction zone and deposition chamber assembly is formed as a unitary/monolithic construction. Furthermore, it should be noted that the vaporizer, the pyrolysis zone, and the vacuum pumping system may be operated in parallel (i.e., simultaneously), in some embodiments. For instance, the vacuum pumping system may be used to pump down the deposition chamber while the vaporizer and pyrolysis zone are used to respectively heat the powdered solid into the first vapor and the first vapor into the second vapor. In some cases, the first vapor comprises a dimer vapor and the second vapor comprises a monomer vapor.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A system for thin-film deposition, comprising:
a welded reaction zone and deposition chamber assembly, the welded reaction zone and deposition chamber assembly comprising:
a reaction zone having a vaporizer and a pyrolysis zone, wherein the vaporizer comprises a body having one or more openings and a loading door;
a deposition chamber configured to hold one or more specimens, the deposition chamber comprising an inlet, an outlet, a lid, and at least one view port;
wherein the pyrolysis zone is positioned between the vaporizer and the deposition chamber, wherein the pyrolysis zone is welded at a first end to the vaporizer using a first weldment and at a second, opposing end to the inlet of the deposition chamber using a second weldment; and
a pumping system, wherein the pumping system is coupled to the outlet of the deposition chamber.

2. The system of claim 1, wherein the vaporizer, the deposition chamber, and the pyrolysis zone are formed as a monolithic or unitary construction, and wherein an internal pressure of the welded reaction zone and deposition chamber assembly is configured to be maintained within a target pressure range for thin-film deposition, wherein the target pressure range is between 1 mTorr to 50 mTorr.

3. The system of claim 1, wherein:
the loading door comprises a vertical loading door;
the vertical loading door is secured to the body using a hinge;
the vertical loading door is shaped and sized to cover a first opening of the one or more openings, the first opening formed at a top end of the body of the vaporizer; and
the vaporizer is configured to receive a powdered solid comprising a raw dimer material, wherein the raw dimer material is placed into the body of the vaporizer via the vertical loading door, and wherein the raw dimer material is configured to be deposited as a thin-film on the one or more specimens in the deposition chamber.

4. The system of claim 3, wherein the body of the vaporizer comprises a second opening positioned along a side of the body, and wherein the second opening is shaped and sized to receive the first end of the pyrolysis zone.

5. The system of claim 1, wherein the at least one view port comprises a plurality of viewports, including at least a first view port positioned on a first side of the deposition chamber and a second view port positioned on a second, different side of the deposition chamber.

6. The system of claim 5, wherein the first view port comprises an elliptical or oval shape and the second view port comprises a circular shape.

7. The system of claim 5, wherein each of the first view port and the second view port comprise an elliptical shape, and one or more of:
an aspect ratio of the first view port is different from an aspect ratio of the second view port; and
a surface area of the first view port is different than a surface area of the second view port.

8. The system of claim 5, wherein the first view port and the second view port comprise a different surface area, a different shape, a different depth, or a combination thereof.

9. The system of claim 1, wherein the at least one view port comprises a plurality of view ports, including at least a first view port and a second view port, and wherein each of the first view port and the second view port are shaped and sized to be received within a corresponding opening formed on a side of the deposition chamber, and wherein each of the first view port and the second view port are secured in the corresponding opening using O-ring gaskets.

10. The system of claim 1, wherein the vaporizer is configured to receive a powdered solid to be deposited as a thin-film on the one or more specimens in the deposition chamber, and wherein the vaporizer is further configured to vaporize or sublimate the powdered solid into a first vapor.

11. The system of claim 10, wherein the first vapor comprises a dimer vapor, and wherein the pyrolysis zone is heated to heat the dimer vapor and transform the dimer vapor to a monomer vapor, and wherein the monomer vapor flows into the deposition chamber.

12. The system of claim 11, wherein:
each of the one or more specimens is selected from a group consisting of an electrical part or wafer, a polymer tube, and a medical device guide wire;
the thin-film deposition comprises a parylene deposition; and
the pyrolysis zone does not include a glass quartz lining.

13. A method of manufacturing a welded reaction zone assembly configured for use in a thin-film deposition process, the method comprising:
providing a vaporizer having a body and a vertical loading door, wherein the vertical loading door is shaped and sized to fit over a first opening formed at a top end of the body;
providing a deposition chamber having an inlet, an outlet, and a lid, and wherein the deposition chamber is configured to hold one or more specimens;
providing a pyrolysis zone having a first end and a second end;
welding the first end of the pyrolysis zone to a second opening formed on a side of the body of the vaporizer and welding the second end of the pyrolysis zone to an inlet of the deposition chamber such that,
the pyrolysis zone is positioned between the vaporizer and the deposition chamber, and
the vaporizer, the deposition chamber, and the pyrolysis zone are formed as a unitary or monolithic construction;
forming one or more viewport openings on one or more sides of the deposition chamber; and
affixing a viewport in each of the one or more viewport openings on the one or more sides of the deposition chamber.

14. The method of claim 13, wherein forming the one or more viewport openings on the side of the deposition chamber comprises:
forming a first viewport opening having a first aspect ratio, wherein the first viewport opening is shaped and sized to receive a first viewport having a same or approximately the same aspect ratio as the first aspect ratio; and
forming a second viewport opening having a second, different aspect ratio, wherein the second viewport opening is shaped and sized to receive a second viewport having a same or approximately the same aspect ratio as the second aspect ratio.

15. The method of claim 13, wherein each of the one or more viewports comprises a window, and wherein each of the one or more viewport openings comprises a receiving port and a flange, each of the receiving port and the flange comprising an exterior side and an interior side, and wherein affixing each of the one or more viewports in a corresponding viewport opening comprises:
positioning the window on the exterior side of the receiving port;
positioning the flange such that at least a portion of a perimeter of the window is arranged within a groove formed between the exterior side of the receiving port and the interior side of the flange;
sealing the window in the groove using a plurality of O-ring gaskets, including at least a first O-ring gasket positioned between the exterior side of the receiving port and a first side of the window and a second O-ring gasket positioned between the interior side of the flange and a second, opposing side of the window;
wherein the first side of the window faces an interior of the deposition chamber and the second side of the window faces an exterior of the deposition chamber.

16. The method of claim 13, wherein:
each of the one or more specimens is selected from a group consisting of an electrical part or wafer, a polymer tube, and a medical device guide wire;
the thin-film deposition comprises a parylene deposition; and
the pyrolysis zone does not include a glass quartz lining.

17. A method of using a welded reaction zone and deposition chamber assembly, the welded reaction zone and deposition chamber assembly configured for use in a thin-film deposition process, the method comprising:
providing the welded reaction zone and deposition chamber assembly, wherein the welded reaction zone and deposition chamber assembly comprises:
a vaporizer having a body and a vertical loading door, wherein the vertical loading door is shaped and sized to fit over a first opening formed at a top end of the body;
a deposition chamber configured to hold one or more specimens, the deposition chamber comprising an inlet, an outlet, a lid, and at least one view port; and
a pyrolysis zone positioned between the vaporizer and the deposition chamber, wherein the pyrolysis zone is welded at one end to the vaporizer using a first weldment and at another, opposing end to the inlet of the deposition chamber using a second weldment;
coupling a pumping system to the outlet of the deposition chamber;
affixing the one or more specimens to an interior of the deposition chamber;
loading a powdered solid through the vertical loading door of the vaporizer, wherein the powdered solid is to be deposited as a thin-film on the one or more specimens in the deposition chamber;
vaporizing or sublimating the powdered solid into a first vapor such that the first vapor flows into the pyrolysis zone;
heating, using the pyrolysis zone, the first vapor such that the first vapor transforms into a second vapor and flows into the deposition chamber; and
pumping down, using the pumping system, the deposition chamber until an internal pressure of the welded reaction zone and deposition chamber assembly is within a target pressure range for thin-film deposition.

18. The method of claim 17, wherein the vaporizer, the deposition chamber, and the pyrolysis zone are formed as a monolithic or unitary construction based at least in part on the first and the second weldments, and wherein the target pressure range is between 1 mTorr to 50 mTorr.

19. The method of claim 18, wherein an internal pressure of the welded reaction zone and deposition chamber assembly is configured to be maintained within the target pressure range for thin-film deposition.

20. The method of claim 17, wherein:
each of the one or more specimens is selected from a group consisting of an electrical part or wafer, a polymer tube, and a medical device guide wire;
the thin-film deposition comprises a parylene deposition; and
the pyrolysis zone does not include a glass quartz lining.
